(19) United States
(12) Patent Application Publication
(10) Pub. No.: US 2007/0262454 A1
(43) Pub. Date: Nov. 15, 2007

(54) Semiconductor device and wiring auxiliary pattern generating method

(76) Inventor: Hidenori Shibata, Osaka (JP)

Correspondence Address: MCDERMOTT WILL & EMERY LLP, 600 13TH STREET, NW, WASHINGTON, DC, 20005-3096, US

(21) Appl. No.: 11/798,179

(22) Filed: May 10, 2007

(30) Foreign Application Priority Data
May 10, 2006 (JP) JP 2006-131224

(51) Int. Cl. H01L 23/52

(52) U.S. Cl. 257/758

(57) ABSTRACT

An area with a low via pattern density is extracted from a semiconductor integrated circuit that includes the first wirings and the second wirings disposed on the upper layer of the first wirings, based on wiring layout information. Then, dummy via patterns connected either to the first wirings or the second wirings are disposed in the peripheral area of the via patterns within the selected area. With this, the dummy via can be disposed even in an area where the wirings are congested.

### BACKGROUND OF THE INVENTION

1. Technical Field

The present invention relates to a semiconductor device, and more particularly, to an LSI wiring structure that comprises dummy vias and dummy wirings.

2. Related Art

In a semiconductor device having multilayer wirings such as a semiconductor integrated circuit, an interlayer insulating film is formed after forming a lower wiring layer, and specific areas of the interlayer insulating film are selectively etched to form via holes thereby to expose the surface of the lower wiring layer. Then, a metal film made of tungsten or the like is formed over the interlayer insulating film including the via holes. Subsequently, the metal film over the interlayer insulating film is removed by CMP (Chemical Mechanical Polishing) method, and an upper wiring layer is formed thereafter.

However, when the areas to be selectively etched (areas where the via holes are formed) are not disposed uniformly over the entire area of the semiconductor device, i.e. when there are variations in the density regarding the layout of the via holes, the etching rate thereof varies. Thus, it is not possible to perform etching uniformly over the entire area of the semiconductor device, which generates variations in the depths of the via holes.

As a technique for overcoming such inconvenience, there is disclosed International Publication WO 2004/006329. FIG. 14 shows plan views and sectional views for illustrating a conventional layout method of dummy vias used for a semiconductor integrated circuit. In this International Publication WO 2004/006329, dummy vias are disposed in the periphery of the vias that are in an area where the via layout density is low, so as to ease the variations in the via layout densities of the substrate. With this, the etching rate can be made uniform to suppress the variation in the depths of the via holes when forming the via holes. Further, when forming the dummy vias, the dummy vias are electrically isolated from the wirings of the semiconductor integrated circuit or connected only to a power supply wiring or a ground wiring in order to avoid an influence imposed upon the semiconductor integrated circuit, such as an increase in the capacity thereof, etc.

### SUMMARY OF THE INVENTION

A conventional semiconductor integrated circuit having the wiring structure as described above comprises dummy wirings and dummy vias which are electrically isolated from the external circuits. In the case of employing such structure, the dummy wirings and the dummy vias are provided in areas where there is no wiring in the first wiring layer or no wiring in the second layer. Thus, the dummy wirings and the dummy vias cannot be provided in an area with highly dense wirings of a highly integrated and highly dense integrated circuit such as a system LSI.

Further, in the case where the dummy wirings and the dummy vias are electrically connected to the power supply wiring and the ground wiring, it is not possible to dispose the dummy wirings and the dummy vias in an area where there is no power supply wiring and ground wiring in the periphery of the dummy wirings and the dummy vias.

As described above, an area with a low via layout density is generated in the area where the dummy wiring and the dummy via cannot be provided and where an isolated via that constitutes a part of a signal line is provided. Therefore, the etching rate at the time of forming the vias becomes changed within the substrate surface. This causes an over-etching, for example, so that there are generated such inconveniences that the interlayer insulating film becomes thin, and the via hole become shallow. Further, in a wiring forming step, the thickness of an antireflective coating (hereinafter referred to as ARC) that is applied after forming the via holes and before forming the upper layer wiring pattern becomes thicker compared to that of the area with dense via layout. Thus, there may be cases where residual substances remain in the via holes. In such a case, the via hole connecting between the lower layer wiring and the upper layer wiring cannot be filled with a metal, so that it is possible generate such an inconvenience that the wiring is cut in this area, etc.

The present invention is designed to overcome the issues of the above-described conventional technique. An object of the present invention therefore is to provide a semiconductor device and a wiring auxiliary pattern generating method with which the distribution of the vias within the substrate face is made uniform.

The semiconductor device of the present invention comprises: first wirings formed on a semiconductor substrate; an interlayer insulating film formed on the first wirings; second wirings formed on the interlayer insulating film; vias for connecting the first wirings and the second wirings through the interlayer insulating film; first dummy wirings formed on a same wiring layer as that of the first wirings; second dummy wirings formed on a same wiring layer as that of the second wirings; first dummy vias for connecting the first dummy wirings and the second wirings; and second dummy vias for connecting the second dummy wirings and the first wirings.

With this structure, it is possible to provide the dummy vias in the area where either the first wirings or the second wirings are provided. Thus, unlike the case of providing the dummy wirings and dummy vias which are connected neither to the first wrings nor to the second wirings, a sufficient number of dummy vias can be disposed even in the area where the first wirings and the second wirings are densely provided. Therefore, it is possible with the semiconductor device of the present invention to prevent short-circuits generated between the various wirings on the first wiring layer and the second wiring layer through dummy vias.

The first dummy wirings are not electrically connected to the first wirings, and the second dummy wirings are not electrically connected to the second wirings. Therefore, there is no influence imposed upon signal transmission by the first, second dummy vias and the first, second dummy wirings.

Among the first wirings, a first wiring that constitutes a clock line or a critical path is connected neither to the second dummy vias nor to the second dummy wirings; and among the second wirings, a second wiring that constitutes a clock line or a critical path is connected neither to the first dummy vias nor to the first dummy wirings. This prevents an influence of the parasitic capacitance generated due to the dummy vias from being imposed upon the signal transmission on the critical path.

The wiring auxiliary pattern generating method of the present invention is a wiring auxiliary pattern generating method for a semiconductor device that includes first wirings, second wirings positioned above the first wirings, and vias for connecting the first wiring and the second wiring. The method comprises the steps of: (a) extracting, when the semiconductor device is sectioned into each area having a first prescribed value in size both longitudinally and laterally, via patterns that are disposed in an area where number of the via patterns is smaller than a second prescribed value, the via patterns being extracted from layout CAD data of the semiconductor device including information on a first wiring pattern as a wiring pattern of the first wirings, a second wiring pattern as a wiring pattern of the second wirings, and a via pattern as a pattern of the vias; (b) performing graphic enlarging processing by using a third prescribed value with one of the corresponding via patterns extracted in the step (a) as a center of enlargement, and outputting a peripheral area of the corresponding via pattern; (c) extracting, from the peripheral area of the corresponding via pattern, an area capable of generating a dummy pattern module that is constituted with a first dummy wiring pattern disposed on a same wiring layer as that of the first wiring pattern, a second dummy wiring pattern disposed on a same wiring layer as that of the second wiring pattern, and a dummy via pattern for connecting the first dummy wiring pattern and the second dummy wiring pattern; and disposing, in the area extracted in the step (c), dummy pattern modules that are only connected either to the first wiring pattern or to the second wiring pattern.

With this method, it is possible to dispose the dummy wirings and the dummy via patterns also in the area where the wiring patterns are densely provided, through disposing dummy pattern modules that are only connected either to the first wiring pattern or to the second wiring pattern in the step (d). This prevents short-circuits between the wiring patterns, resulting in improved yields when manufacturing the semiconductor devises. The dummy via pattern is connected either to the first wiring pattern or to the second wiring pattern, so that an increase in the parasitic capacitance due to the dummy vias can be calculated accurately by using LPE (Layout Parameter Extraction), which extracts the wiring resistance and the capacitance on the circuit.

Each step of the wiring auxiliary pattern generating method according to the present invention is achieved by a dedicated design tool installed in a computer or by a dedicated designing device. Further, data inputted in each step of the present invention may be stored in a storage device such as a memory.

Furthermore, the step (c) includes: (c1) applying graphic enlarging processing on the first wiring pattern in the peripheral area of the corresponding via pattern by using a value that is equal to or more than a minimum space between the first wiring patterns defined in a design rule, and outputting a result of the graphic enlarging processing as a first layout prohibited area where layout of the first dummy wiring pattern is prohibited; (c2) applying graphic enlarging processing on the second wiring pattern in the peripheral area of the corresponding via pattern by using a value that is equal to or more than a minimum space between the second wiring patterns defined in a design rule, and outputting a result of the graphic enlarging processing as a second layout prohibited area where layout of the second dummy wiring pattern is prohibited; and (c3) performing graphic inverting processing respectively on the first layout prohibited area and the second layout prohibited area, performing graphic exclusive OR operation processing on each of outputted areas, and outputting results of the processing as areas capable of generating the dummy pattern module. By performing such graphic processing, it is possible to efficiently extract the area capable of disposing a dummy pattern module that is only connected either to the first wiring pattern or to the second wiring pattern.

The method further comprises (e) selecting, among the dummy pattern modules outputted in the step (d), only a dummy pattern module that is disposed in an area other than an area where there are formed an analog circuit and a memory circuit whose circuit operations may be influenced by addition of the first dummy wiring or the second dummy wiring and the dummy via pattern, and outputting the dummy pattern module. With this, the dummy pattern module can be disposed without affecting the circuit operations of the analog circuit and the memory circuit.

In addition, the method further comprises the steps of: (f) extracting a net list containing signal path information regarding signals that may have delay fluctuations from net list CAD data of the semiconductor device; (g) extracting a wiring pattern contained in the net list that is extracted in the step (f); and (h) eliminating a dummy pattern module positioned on the wiring pattern extracted in the step (g), among the dummy pattern modules outputted in the step (d). This makes it possible to prevent inconveniences such as delay in signal propagation and deterioration in the operation frequency of the circuit caused by an increase in the parasitic capacitance generated due to the dummy via pattern and the dummy wiring pattern.

Since the net list extracted in the step (f) includes the critical path and the clock line, it is possible to suppress generation of inconveniences such as delay in signal propagation and deterioration in the operation frequency of the circuit.

The method further comprises the steps of: at least after the step (d), (i) judging whether or not a sum of the corresponding via patterns and the dummy via patterns disposed in the area extracted in the step (b) is equal to or more than the second prescribed value, and whether or not the sum is equal to or less than a fourth prescribed value; and (j) processing the dummy via patterns when it is judged in the step (i) that the sum of the via patterns and the dummy via patterns is smaller than the second prescribed value, and reducing the dummy pattern modules when the sum is larger than the fourth prescribed value. This effectively prevents generation of over-etching and under-etching during the wiring forming step of the semiconductor integrated circuit.

When it is judged in the step (i) that the sum of the via patterns and the dummy via patterns is smaller than the second prescribed value, it is preferable to perform graphic enlarging processing on the dummy via patterns and the via patterns in the step (j) by using a fifth prescribed value. The fifth prescribed value is a value defined by the method used for the manufacturing steps of the semiconductor device.

When it is judged in the step (i) that the sum of the via patterns and the dummy via patterns is larger than the fourth prescribed value, dummy pattern modules distant from the via patterns are eliminated in the step (j), among the dummy pattern modules disposed within the area that is extracted in the step (c). This makes it possible to securely prevent the inconveniences such as short-circuits generated between the wirings due to the metal that is remained on the interlayer insulating film because of under-etching, at least in the areas close to the via patterns.

When it is judged in the step (i) that the sum of the via patterns and the dummy via patterns is larger than the fourth prescribed value, the dummy pattern modules connected to the first wiring patterns disposed on every other wiring grid lines and the dummy pattern modules connected to the second wiring patterns disposed on every other wiring grid lines are eliminated in the step(j). This expands the space between the dummy via patterns, so that generation of inconveniences such as short-circuits between the wirings or between the wirings and the dummy wirings can be suppressed during the actual manufacturing steps of the semiconductor device.

As described above, the wiring auxiliary pattern generating method of the present invention disposes the dummy via pattern that is only connected either to the first wiring pattern or to the second wiring pattern. Thus, the dummy via pattern can be disposed even in the area where the wirings are densely provided. As a result, it becomes possible to set the sum of the via patterns and the dummy via patterns within a prescribed area to be in a proper range.

Furthermore, in the semiconductor device to which the wiring auxiliary pattern of the present invention is applied, the sum of the vias and the dummy vias within a prescribed range is set to be within a proper range. Therefore, probability of generating inconveniences such as under-etching and connection failure can be suppressed low.

### BRIEF DESCRIPTION OF THE DRAWINGS

FIG. 1 is a flowchart for illustrating a wiring auxiliary pattern generating method according to a first embodiment of the present invention;

FIG. 2 is a flowchart for illustrating in detail a part of the steps in the wiring auxiliary pattern generating method according to the first embodiment;

FIG. 3A is a plan view for showing a wiring layout when a semiconductor integrated circuit is view from above, and FIG. 3B is a sectional view of the semiconductor integrated circuit taken along the line IIIb-IIIb of FIG. 3A;

FIG. 4A is a plan view for showing a wiring layout when a semiconductor integrated circuit to which the wiring auxiliary pattern generating method according to the first embodiment is applied is viewed from above, and FIG. 4B is a sectional view of the semiconductor integrated circuit taken along the line IVb-IVb of FIG. 4A;

FIG. 5A is a diagram for describing the procedure for applying the wiring auxiliary pattern generating method according to the first embodiment to the wiring pattern example shown in FIG. 4;

FIG. 5B is a diagram for describing the procedure for applying the wiring auxiliary pattern generating method according to the first embodiment to the wiring pattern example shown in FIG. 4;

FIG. 5C is a diagram for describing the procedure for applying the wiring auxiliary pattern generating method according to the first embodiment to the wiring pattern example shown in FIG. 4;

FIG. 5D is a diagram for describing the procedure for applying the wiring auxiliary pattern generating method according to the first embodiment to the wiring pattern example shown in FIG. 4;

FIG. 5E is a diagram for describing the procedure for applying the wiring auxiliary pattern generating method according to the first embodiment to the wiring pattern example shown in FIG. 4;

FIG. 5F is a diagram for describing the procedure for applying the wiring auxiliary pattern generating method according to the first embodiment to the wiring pattern example shown in FIG. 4;

FIG. 5G is a diagram for describing the procedure for applying the wiring auxiliary pattern generating method according to the first embodiment to the wiring pattern example shown in FIG. 4;

FIG. 5H is a diagram for describing the procedure for applying the wiring auxiliary pattern generating method according to the first embodiment to the wiring pattern example shown in FIG. 4;

FIG. 5I is a diagram for describing the procedure for applying the wiring auxiliary pattern generating method according to the first embodiment to the wiring pattern example shown in FIG. 4;

FIG. 5J is a diagram for describing the procedure for applying the wiring auxiliary pattern generating method according to the first embodiment to the wiring pattern example shown in FIG. 4;

FIG. 6 is a diagram for showing a modification example of a dummy pattern module generating method according to the first embodiment;

FIG. 7 is a flowchart for showing a modification example of a dummy pattern module generating method according to a second embodiment of the present invention;

FIG. 8 is a flowchart for illustrating in detail the steps shown in FIG. 7 in the wiring auxiliary pattern generating method according to the second embodiment;

FIGS. 9A and 9B are plan views for describing the wiring auxiliary pattern generating method according to the second embodiment;

FIGS. 10 is a flowchart for illustrating the wiring auxiliary pattern generating method according to a third embodiment of the present invention;

FIGS. 11A and 11B are plan views for describing the wiring auxiliary pattern generating method according to the third embodiment;

FIGS. 12 is a flowchart for illustrating the wiring auxiliary pattern generating method according to a fourth embodiment of the present invention;

FIGS. 13A, 13B, and 13C are plan views for describing the wiring auxiliary pattern generating method according to the fourth embodiment; and

FIG. 14 shows plan views and sectional views for illustrating a conventional dummy via arranging method for a semiconductor integrated circuit.

### DESCRIPTION OF THE PREFERRED EMBODIMENTS

### First Embodiment

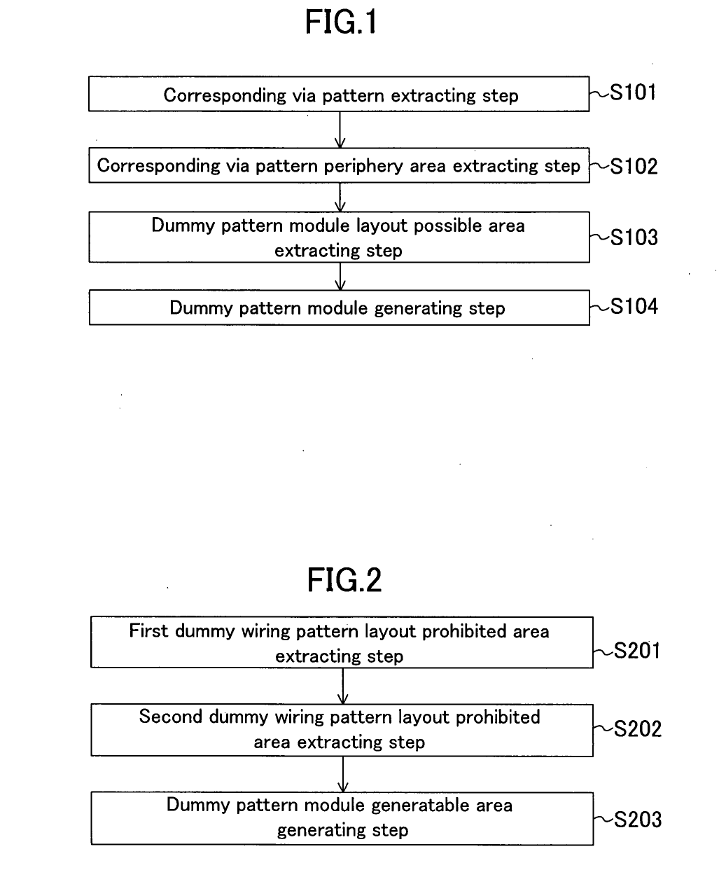

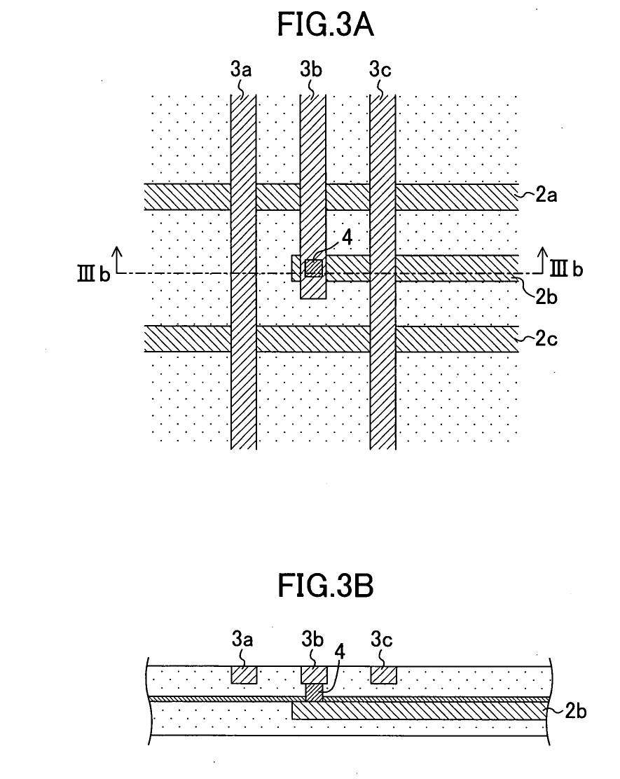

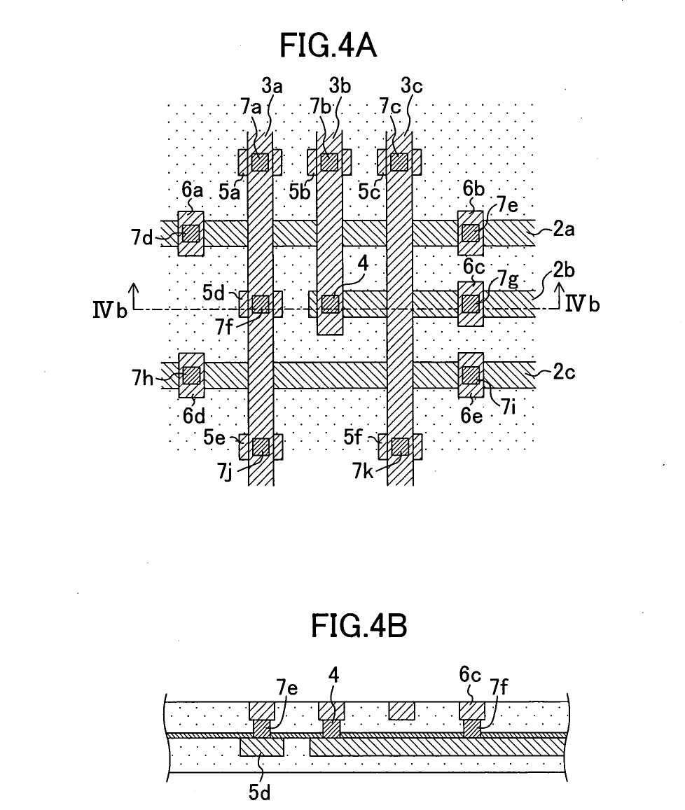

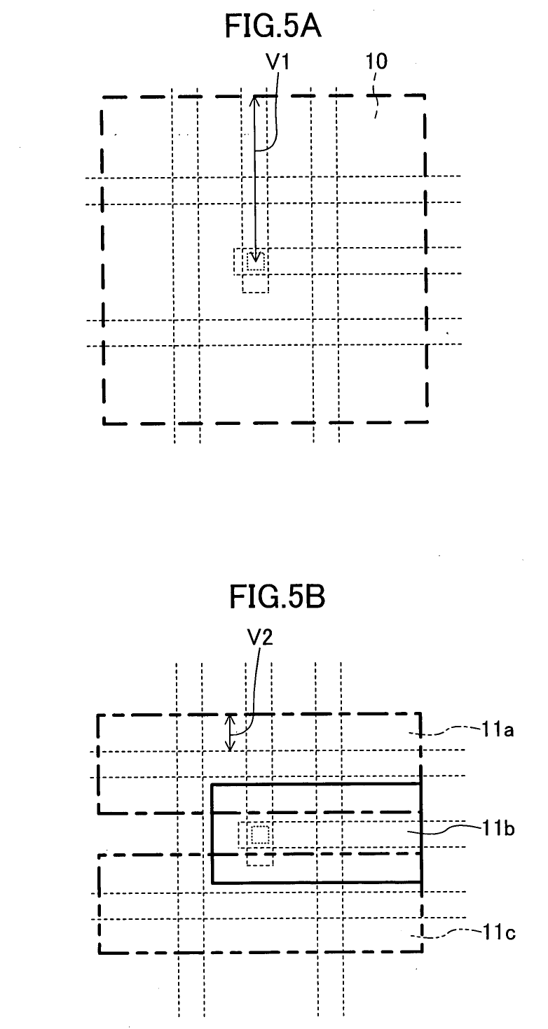

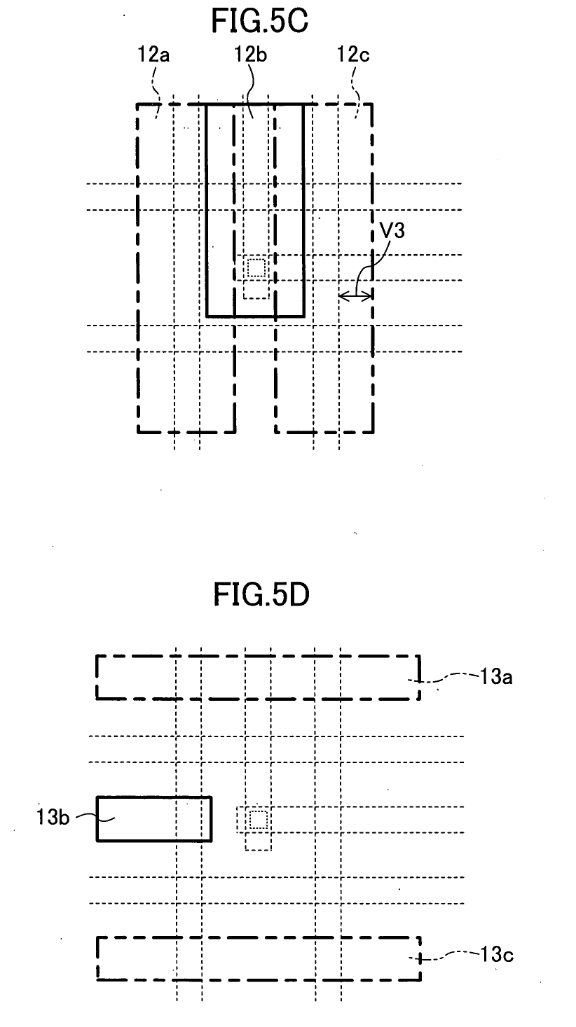

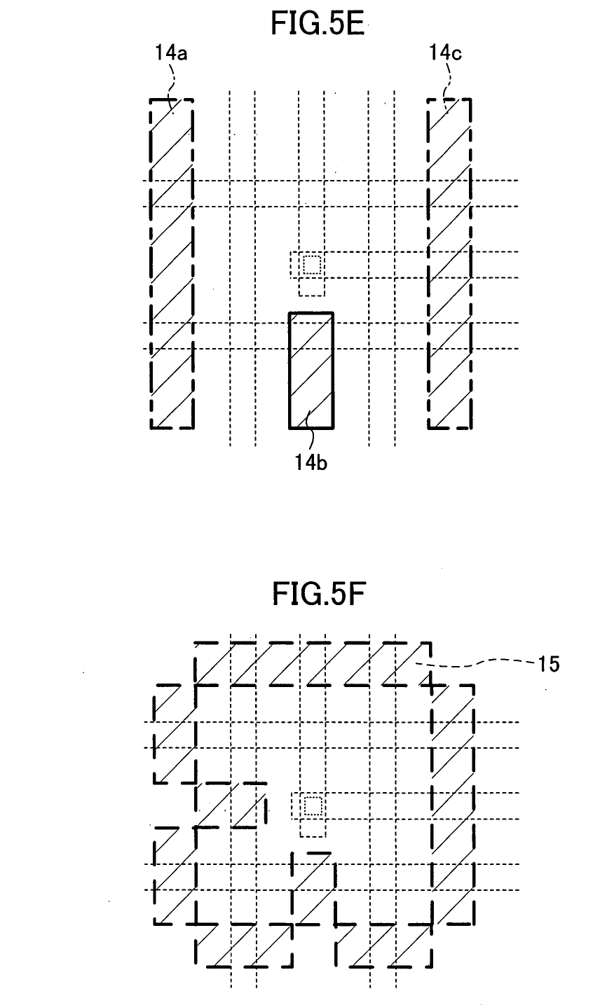

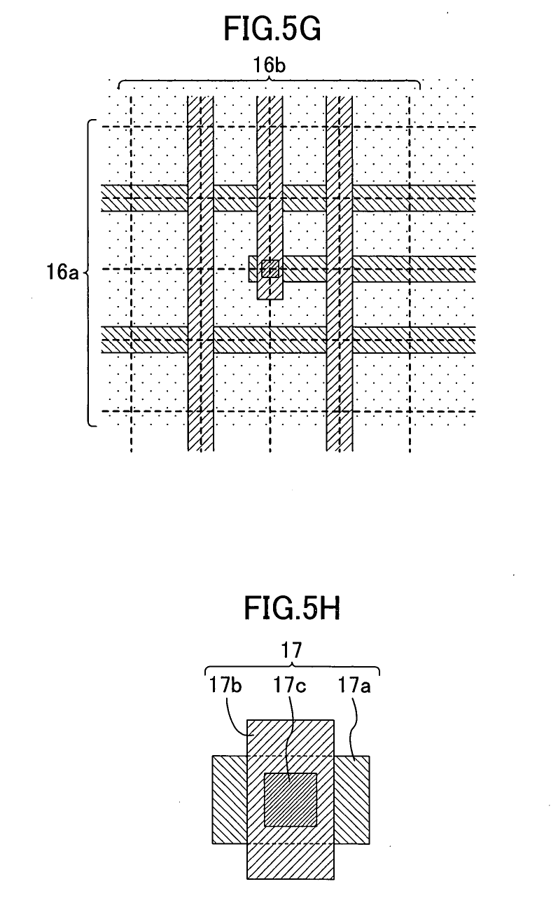

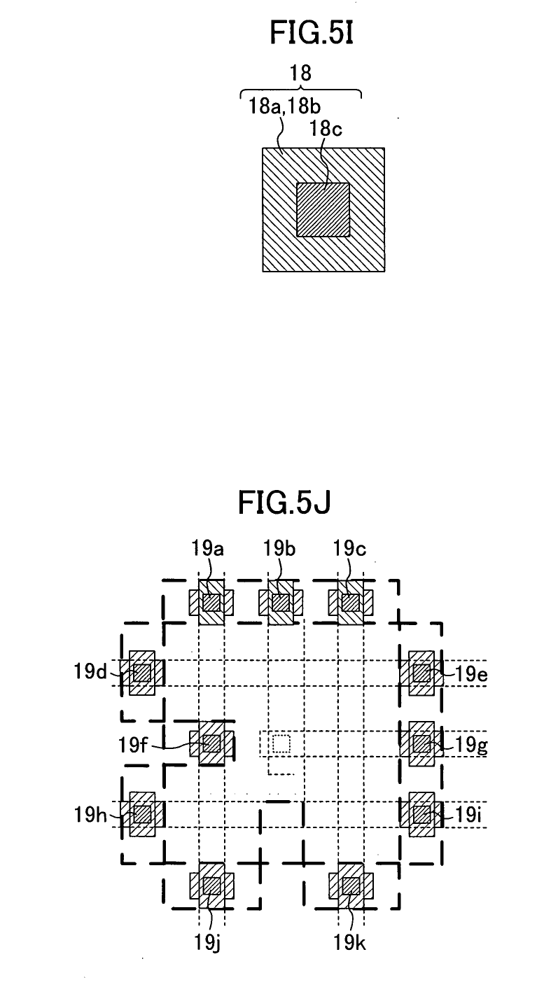

FIG. 1 is a flowchart for illustrating a wiring auxiliary pattern generating method according to a first embodiment of the present invention, and FIG. 2 is a flowchart for illustrating in detail a part of the steps in the wiring auxiliary pattern generating method according to the first embodiment. Further, FIG. 3A is a plan view for showing a wiring layout when a semiconductor integrated circuit is viewed above, and FIG. 3B is a sectional view of the semiconductor integrated circuit taken along the line IIIb-IIIb of FIG. 3A. FIG. 4A is a plan view for showing a wiring layout when a semiconductor integrated circuit to which the wiring auxiliary pattern generating method according to the first embodiment is applied is viewed from above, and FIG. 4B is a sectional view of the semiconductor integrated circuit taken along the line IVb-IVb of FIG. 4A. FIGS. 5A -5J are diagrams for describing the procedure for applying the wiring auxiliary pattern generating method according to the first embodiment to the wiring pattern example shown in FIG. 4. In FIGS. 3-5, there are illustrated patterns of wirings (hereinafter referred to as “first wirings”) that are formed on a first wiring layer, patterns of wirings (hereinafter referred to as “second wirings”) that are formed on a second wiring layer, and patterns of vias (dummy vias) which connect the wirings of the first wiring layer and the wirings of the second wiring layer.

The wiring auxiliary pattern generating method of the embodiment will be described below by referring to the above drawings. Each step shown in FIG. 1 and FIG. 2 is performed by an analyzing tool (a layout inspection tool) or the like, which allows a computer to execute the data processing. This layout inspection tool inspects whether or not the dimensions and the like of the semiconductor layout pattern satisfy the design rule.

First, as shown in FIG. 1, via patterns in an area that corresponds to a prescribed condition are extracted in a step s101 by using layout CAD data of a semiconductor integrated circuit. Specifically, for example, data of the layout CAD containing the wiring layout information is inputted to a computer to which an analyzing tool is mounted. In this step, areas in size having a first prescribed value both longitudinally and laterally are generated with respect to the respective via patterns, and the number of via patterns included in each area is counted. When the number of via patterns in this area is smaller than a second prescribed value, the data of the corresponding via patterns is outputted. The size of the area where the number of via patterns is counted and the second prescribed value are the values defined by a manufacturing device and a manufacturing method of a semiconductor device. When the number of via patterns within a prescribed size area is smaller than the second prescribed value, it means that the density of the via patterns in that area is low and the via patterns are in an isolated state.

FIGS. 3A and 3B illustrate an example of the area including the via pattern 4 that is extracted in this step. In this example, first wiring patterns 2a, 2b, 2c are disposed in parallel to each other on the first wiring layer, and second wiring patterns 3a, 3b, 3c which are orthogonal to the first wiring patterns 2a, 2b, 2c, respectively, are disposed on the second wiring layer. The via pattern 4 for connecting the first wiring pattern 2b and the second wiring pattern 3b is provided in this area; however, the number of via pattern 4 is smaller than the second prescribed value.

When there is such an area where the density of the via patterns is low, over-etching occurs in the manufacturing steps of the semiconductor device and there are variations generated in the depths of the vias, unless the layout is modified.

Next, peripheral areas of the via patterns that are extracted in the step s101 are extracted in a step s102 shown in FIG. 2. Specifically, there is performed graphic enlarging processing which extracts, as the peripheral areas, ranges that are obtained by extending the dimensions in both the vertical direction and the lateral direction by a third prescribed value with respect to the via patterns extracted in the step s101. Extraction of the peripheral area (step s102) is performed on all the via patterns that are extracted in the step s101. The third prescribed value is a value defined by the manufacturing device and the manufacturing method of the semiconductor device. Through providing the dummy via pattern within the area of the third prescribed value, it is possible to prevent the via pattern from being isolated. Thus, the areas outputted in the step S102 become the areas for disposing the dummy via patterns. FIG. 5A illustrates a pattern 10 having the range obtained by extending the dimensions by the third prescribed value v1 in the longitudinal and lateral directions with respect to the center of the via pattern 4. The pattern 10 is an area where isolation of the via pattern can be prevented through disposing the dummy via pattern within that area.

Next, an area where a dummy pattern module can be disposed is extracted in a step s103. The term “dummy pattern module” indicates a combination of the dummy pattern formed on the first wiring layer and the second wiring layer and the dummy via pattern connected to that dummy pattern.

In this step, among the areas outputted in the step s102, an area where the dummy via pattern can be disposed is extracted taking into consideration the wiring patterns on the first wiring layer and the second wiring layer. The processing of this step will be described in more detail.

FIG. 2 is a flowchart for showing an example of the detailed flow of the step s103. As shown, in the step s103, first, there is performed a step s201 for extracting, from the areas outputted in the step s102, an area where the dummy pattern cannot be provided within the first wiring layer. That is, graphic enlarging processing is performed on the wiring patterns of the first wiring layer in the peripheral areas of the via patterns that are outputted in the step s102, and the result thereof is outputted as a first dummy wiring pattern layout prohibited area. The enlarging amount of the graphic enlarging processing is a value greater than the minimum space between the wiring patterns of the first wiring layer defined in the design rule, which is a value desired to be secured as the space between the wiring pattern and the dummy wiring pattern on the first wiring layer. By setting the space between the wiring pattern and the dummy pattern as equal to or more than the minimum space on the first wiring layer, it is possible to prevent a short-circuit between the wiring pattern and the dummy wiring pattern and to sufficiently reduce the inter-wiring capacity. FIG. 5B illustrates an output example of the graphic enlarging processing when the minimum space between the wiring patterns is set as v2. In this example shown in FIG. 5B, areas where the distances from the first wiring patterns 2a, 2b, and 2c within the first wiring layer (see FIG. 3A) are equal to or less than v2 are outputted as patterns 11a, 11b, and 11c, respectively.

Next, in a step s202, an area where the dummy pattern cannot be disposed within the first wiring layer is extracted from the areas outputted in the step s102. That is, graphic enlarging processing is performed on the wiring pattern of the second wiring layer in the peripheral areas of the via patterns that are outputted in the step s102, and the result thereof is outputted as a second dummy wiring pattern layout prohibited area. The enlarging amount of the graphic enlarging processing is a value equal to or more than the minimum space between the wiring patterns of the second wiring layer defined in the design rule, which is a value desired to be secured as the space between the wiring pattern and the dummy wiring pattern on the second wiring layer. FIG. 5C illustrates an output example of the graphic enlarging processing when the minimum space between the wiring patterns is set as v3. In this example shown in FIG. 5C, the areas where the distances from the second wiring patterns 3a, 3b, and 3c within the second wiring layer (see FIG. 3A) are equal to or less than v3 are outputted as patterns 12a, 12b, and 12c, respectively.

Next, an area capable of disposing a dummy pattern module is generated in a step s203. In this step, after performing graphic inverting processing on each of the first dummy wiring pattern layout prohibited areas outputted in the step s201 and the second dummy wiring pattern layout prohibited area outputted in the step s202, exclusive OR operation processing is performed. The result of this processing is outputted as the areas where the dummy pattern module can be disposed.

FIG. 5D shows patterns 13a, 13b, and 13c, which are obtained by performing graphic inverting processing on the patterns 11a, 11b, and 11c (see FIG. 5B) within the area of the pattern 10, respectively. FIG. 5E shows patterns 14a, 14b, and 14c, which are obtained by performing graphic inverting processing on the patterns 12a, 12b, and 12c (see FIG. 5C) within the area of the pattern 10, respectively. In this step (step s203), as shown in FIG. 5F, an area where there is no overlap between the patterns 12a, 12b, 12c and the patterns 14a, 14b, 14c is extracted as a pattern 15. By disposing the dummy pattern module constituted with the dummy via pattern and the dummy wiring pattern in the area of the pattern 15, it is possible to generate the dummy pattern module that is connected either to the first wiring patterns 2a, 2b, 2c or to the second wiring patterns 3a, 3b, 3c.

Next, in a step s104, the dummy pattern module is disposed within the area that is extracted in the step s103. As shown in FIG. 5H, a dummy pattern module 17 is constituted with a first dummy wiring pattern 17a formed on the first wiring layer, a second dummy wiring pattern 17b formed on the second wiring layer, and a dummy via pattern 17c that connects the first dummy wiring pattern 17a and the second dummy wiring pattern 17b. The sizes (plane sizes) of the first dummy wiring pattern 17a, the second dummy wiring pattern 17b, and the dummy via pattern 17c are determined within the ranges to comply with design rules that are defined by the manufacturing device and the manufacturing method of the semiconductor device.

FIG. 5G shows a wiring grid 16a of the first wiring layer and a wiring grid 16b of the second wiring layer. In this step (step s104), the dummy pattern modules 17 are disposed at the intersection points between the wiring grid 16a and the wiring grid 16b in the area of the pattern 15. Specifically, dummy pattern modules 19a, 19b, 19c, 19d, 19e, 19f, 19g, 19h, 19i, and 19k shown in FIG. 5J are outputted. Thereafter, the dummy pattern modules 19a-19k are superimposed on the first patterns 2a-2c, the second wiring patterns 3a-3c, and the via pattern 4. As a result, the first dummy wiring patterns, the second dummy wiring patterns of the dummy pattern modules that are overlapped with the first wiring patterns 2a-2c, the second wiring patterns 3a-3c are synthesized with the first wiring patterns 2a-2c, the second wiring patterns 3a-3c, thereby generating a semiconductor integrated circuit containing the wiring pattern that is constituted with first dummy wiring patterns 5a-5f, second wiring patterns 6a-6e, and dummy via patterns 7a-7k. The dummy pattern modules 19d, 19e, 19g, 19h, and 19i, contain dummy via patterns (first dummy via patterns) that are connected to one of the first wiring patterns, and the dummy pattern modules 19a, 19b, 19c, 19f, 19j, and 19k contain dummy via patterns (second dummy via patterns) that are connected to one of the second wiring patterns.

FIGS. 4A and 4B illustrate the semiconductor integrated circuit containing the wiring patterns obtained as described above.

A first dummy wiring pattern 5a is connected to the second wiring pattern 3a by a dummy via pattern 7a, a first dummy wiring pattern 5b is connected to the second wiring pattern 3b by a dummy via pattern 7b, a first dummy wiring pattern 5c is connected to the second wiring pattern 3c by a dummy via pattern 7e, a first dummy wiring pattern 5d is connected to the second wiring pattern 3a by a dummy via pattern 7f, a first dummy wiring pattern 5e is connected to the second wiring pattern 3a by a dummy via pattern 7j, a first dummy wiring pattern 5f is connected to the second wiring pattern 3c by a dummy via pattern 7k, a second dummy wiring pattern 6a is connected to the first wiring pattern 2a by a dummy via pattern 7d, a second dummy wiring pattern 6b is connected to the first wiring pattern 2a by a dummy via pattern 7e, a second dummy wiring pattern 6c is connected to the first wiring pattern 2b by a dummy via pattern 7g, a second dummy wiring pattern 6d is connected to the first wiring pattern 2c by a dummy via pattern 7h, and a second dummy wiring pattern 6e is connected to the first wiring pattern 2c by a dummy via pattern 7i. In the semiconductor integrated circuit of this embodiment, the dummy via patterns 7a-7k and the via pattern 4 are formed through the interlayer insulating film.

As described above, all of the first dummy wiring patterns, the second dummy wiring patterns, and the dummy via patterns are respectively connected either to the first wiring patterns or the second wiring patterns. Further, in this semiconductor integrated circuit, the dummy via patterns are disposed in the periphery of the area with a low via pattern density, so that the sum of the number of dummy via patterns and the number of via patterns within a prescribed range is set as at least equal to or more than the second prescribed value.

As described above, the method according to the first embodiment of the present invention disposes the dummy vias in the area where there exists either the first wiring or the second wiring. Therefore, the dummy vias can be efficiently disposed in the area where the first wiring, the second wiring are densely disposed and the via density is low, compared to the case of disposing the dummy vias that are electrically connected neither to the first wiring nor to the second wiring, i.e. where the dummy vias are disposed only in the area where there is neither the first wiring nor the second wiring.

In the semiconductor integrated circuit designed with the method of this embodiment, the second dummy wiring connected to the dummy via is not electrically connected to the second wiring when the dummy via is disposed on the first wiring. Further, when the dummy via is disposed under the second wiring, the first dummy wiring connected to the dummy via is not electrically connected to the first wiring. Thus, it is possible to prevent the signal wiring, the power supply wiring, and the ground wiring disposed on the first wiring layer and the second wiring layer of the semiconductor integrated circuit from being connected to each other through the dummy via, i.e. it is possible to avoid a short-circuit generated between those wirings.

Further, in the semiconductor integrated circuit of this embodiment, the dummy via is electrically connected either to the first wiring or to the second wiring. Thus, it is possible to calculate an increase in the parasitic capacitance precisely with LPE (Layout Parameter Extraction) which extracts the resistance, the capacitance, and the like of the wirings on the circuit.

In the step s101, the semiconductor integrated circuit may be sectioned into each area that has the first prescribed value in length both longitudinally and laterally, and the number of the via patterns contained within each area may be counted to extract the area where the number of via patterns is smaller than the second prescribed value. Further, the semiconductor integrated circuit may be sectioned into each area whose square measure is the first prescribed value.

In the explanation of the step s104, the dummy pattern module 17 is used as the shape of the dummy pattern module. However, the shape of the dummy pattern module is not limited to that. It is also possible to use a dummy pattern module 18 that is constituted with a first wiring pattern 18a and a second wiring pattern 18b having the same plane shape, and a dummy via pattern 18c as shown in FIG. 51, for example, insofar as the design rules of the first wiring pattern, the second wiring pattern, and the via pattern are satisfied.

The results extracted or outputted in the steps s101-s104 and the steps s201-s203 shown in FIG. 1 and FIG. 2 may be stored in a memory of a computer or the like after each step is completed. By saving at least the data regarding the dummy pattern module generated in the step s104 to a storage device such as a memory, the data can further be processed to be used also for designing a semiconductor integrated circuit.

Further, in the explanation of the step s102, used as the corresponding via pattern peripheral area is the pattern that is obtained by enlarging the quadrilateral via pattern such as the pattern 10 into a quadrilateral shape. However, the shape of the corresponding via pattern peripheral area is not limited to that. For example, a pattern that is enlarged into a regular octagon can also be used for the quadrilateral via pattern. This makes it possible to have the uniform distances from the center of the corresponding via pattern peripheral area to each side in longitudinal directions, lateral directions, and oblique directions at an angle of 45 degrees.

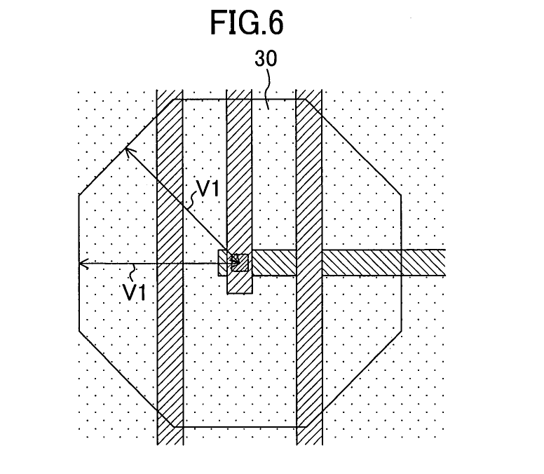

FIG. 6 is a diagram for showing a modification example of the dummy pattern module generating method according to the first embodiment. In FIG. 6, a pattern 30 is obtained by enlarging the via pattern 4 into a regular octagon shape by the enlarging amount v1, whereas the pattern 10 is obtained by enlarging the via pattern 4 into a quadrilateral shape by the enlarging amount v1. While use of the quadrilateral-enlarged pattern 10 facilitates generation of the peripheral area, use of the pattern 30 that is enlarged in an octagonal shape with respect to the via pattern 4 makes it possible to estimate the physical phenomena that may occur at the time of manufacture more exactly.

### Second Embodiment

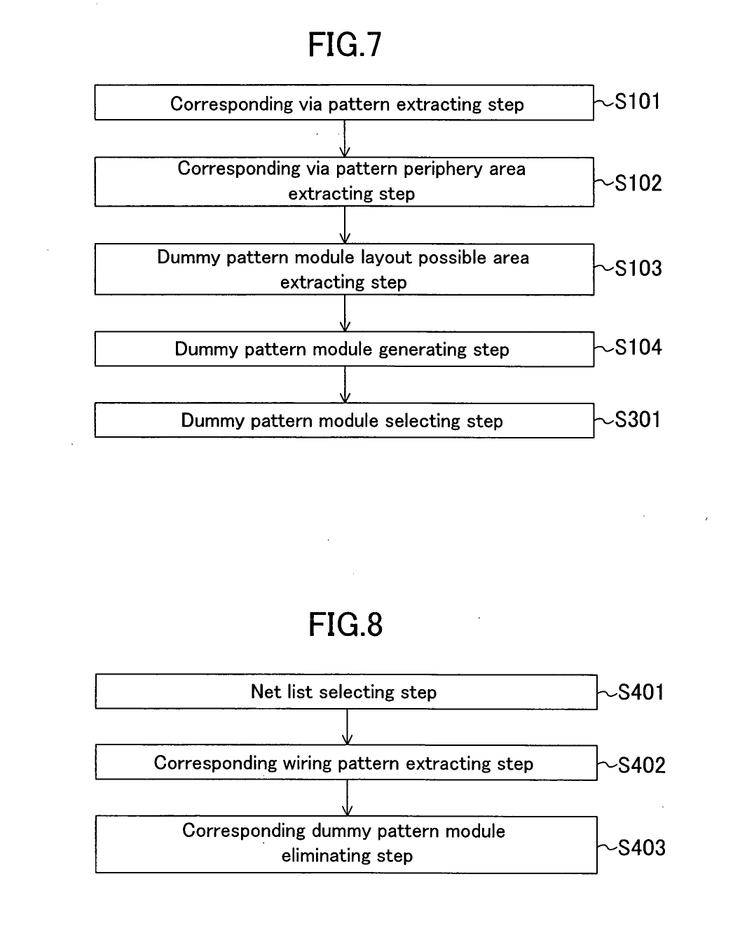

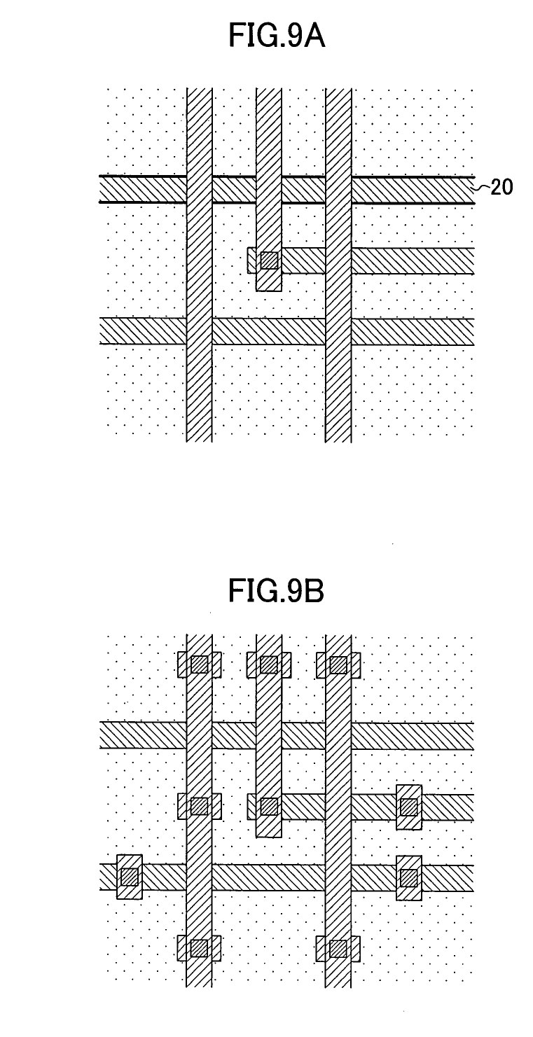

FIG. 7 is a flowchart for illustrating the dummy pattern module generating method according to a second embodiment of the present invention. FIG. 8 is a flowchart for illustrating in detail the steps shown in FIG. 7 in the wiring auxiliary pattern generating method according to the second embodiment. FIGS. 9A and 9B are plan views for describing the wiring auxiliary pattern generating method of this embodiment, which illustrate examples of the actual pattern. FIG. 5 is used for describing the wiring auxiliary pattern generating method of this embodiment.

The wiring auxiliary pattern of this embodiment is generated in the following manner.

First, as shown in FIG. 7, the steps s101-s104 are carried out. In the step s104, the dummy pattern modules 19a-19k shown in FIG. 5J are outputted.

Then, among the dummy pattern modules generated in the step s104, dummy pattern modules connected to a part of the wiring patterns are eliminated in a step s301. Specifically, among the dummy module patterns generated in the step s104, eliminated are dummy pattern modules which are electrically connected to wirings such as the critical paths and clock lines that require prevention of an influence such as an increase in the parasitic capacitance caused by the dummy pattern modules. Alternatively, in the case where the area where the dummy pattern modules are disposed is an analog circuit or a memory circuit, dummy pattern modules that are in the area intended to be free of an influence imposed upon the circuit operations are eliminated. This prevents an increase in the parasitic capacitance caused by dummy pattern modules and a resulting influence on the circuit operations.

FIG. 8 is a flowchart for illustrating a detailed procedure of the step s301. Each step shown in FIG. 7 and FIG. 8 can be executed not only by, for example, a design tool installed in a computer but also by a designing device that comprises circuits for performing the processing of each step.

In the step s301, a step s401 is carried out first. In this step, a net list that is susceptible to the influence of delay fluctuation in the semiconductor integrated circuit is extracted from net list CAD data of the semiconductor integrated circuit. For this step, the first wiring patterns 2a-2c, the second wiring patterns 3a-3c, the pattern 10, the dummy pattern modules 19a-19k, and the net list information of the semiconductor integrated circuit are inputted in advance to the design tool or the like. Then, a signal path that influences the operation speed of the semiconductor integrated circuit due to the occurrence of signal propagation delay is analyzed by using the net list, and it is outputted as critical path information.

Then, in a step s402, the first wiring pattern and the second wiring pattern corresponding to the aforementioned condition are extracted from the net list that is selected in the step s401 as the corresponding first wiring pattern and the corresponding second wiring pattern. A wiring path that corresponds to the critical path information outputted in the step s401 is extracted from the first wiring patterns 2a-2c, the second wiring patterns 3a-3c, and the pattern 10, and a pattern 20 shown in FIG. 9A is outputted as the corresponding wiring pattern.

Subsequently, in a step s403, dummy pattern modules disposed at the positions to be electrically connected to the corresponding first wiring pattern and the corresponding second wiring pattern extracted in the step s402 are eliminated from the dummy pattern modules 19a-19k that are shown in FIG. 5J. That is, among the dummy pattern modules 19a-19k, the dummy pattern modules 19d and 19e, which are disposed on the pattern 20, which is outputted in the step s402, are extracted and eliminated. As a result, the dummy pattern modules 19a-19c, and 19f-19k are outputted.

In the case described above, the dummy pattern modules 19d and 19e become a dummy wiring pattern and a dummy via pattern which are electrically connected to the path of the critical path, thereby adding capacitance to the critical path. Due to the presence of the dummy pattern modules 19d and 19e, the amount of signal propagation delay in the critical path is increased, which influences the operation speed of the semiconductor integrated circuit. With the method of this embodiment, however, the dummy pattern modules 19d and 19e disposed on the path of the critical path are eliminated in the dummy pattern module selecting step s301, thereby preventing the influence of the dummy wiring pattern and the dummy via pattern imposed upon the operation speed of the semiconductor integrated circuit.

In the explanation of the dummy pattern module selecting step s301, it is described by specifically referring to the case of the critical path. However, it is not limited only to that case. For example, the dummy pattern modules can be eliminated in the same manner as the wiring corresponding to the signal path of the clock line.

Further, the dummy pattern module selecting step s301 has been described by referring to the case of eliminating the dummy wiring pattern and the dummy via pattern on a specific signal path. However, it is not limited to that case. For example, for circuits such as the analog circuit and the memory circuit whose circuit operations are influenced by adding the dummy wiring pattern and the dummy via pattern, it may be replaced with elimination of the dummy wiring pattern and the dummy via pattern in that area.

### Third Embodiment

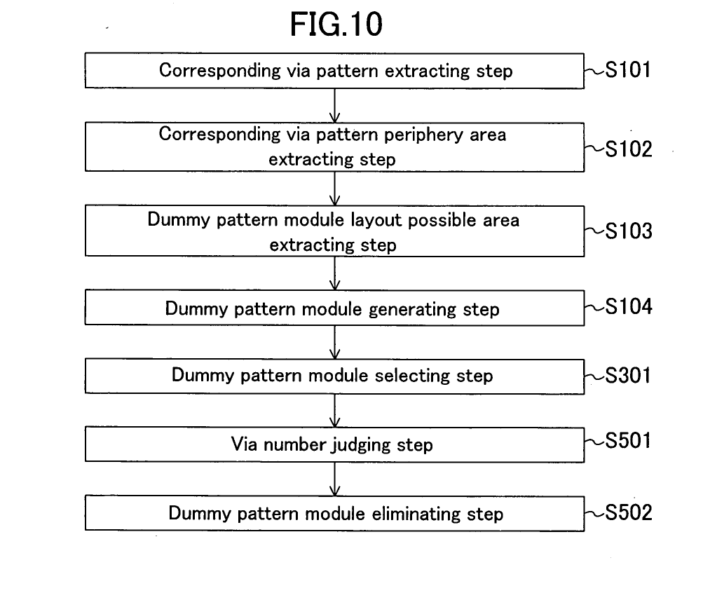

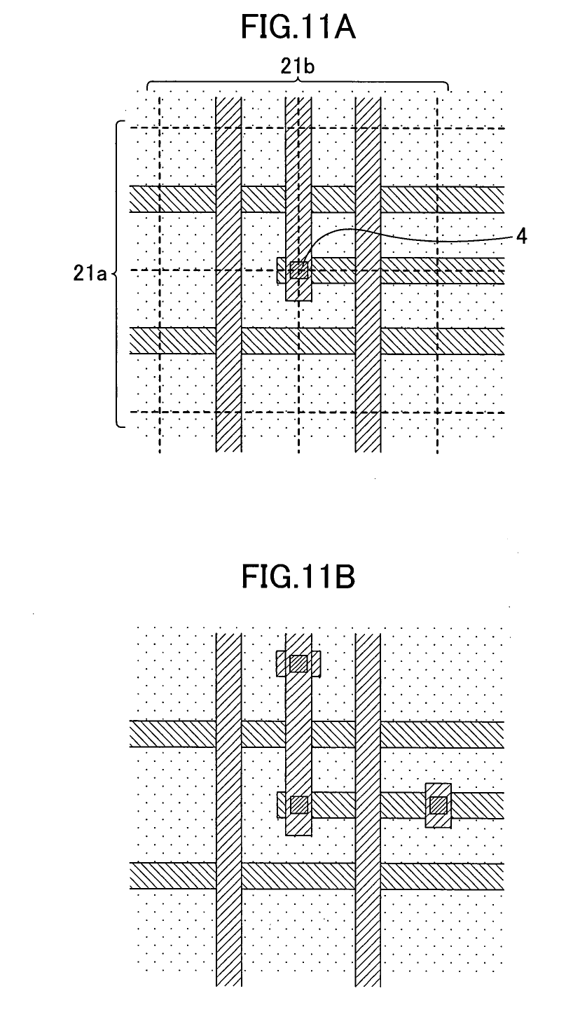

FIG. 10 is a flowchart for illustrating the wiring auxiliary pattern generating method according to a third embodiment of the present invention. FIGS. 11A and 11B are plan views for describing the wiring auxiliary pattern generating method according to the third embodiment, which respectively illustrate actual pattern examples. FIG. 5, which is referred to in describing the first embodiment, is used for describing the wiring auxiliary pattern generating method of this embodiment.

The wiring auxiliary pattern of this embodiment is generated in the following manner.

First, the steps s101-s104 and the step s301 shown in FIG. 10 are carried out. The steps s101-s104 are the same steps as those described in the first embodiment, and the step s301 is the same step as that described in the second embodiment. That is, the dummy pattern modules 19a-19k shown in FIG. 5J are outputted in the step s104, and dummy pattern modules 19d, 19e among the dummy pattern modules 19a-19k are eliminated in the step s301.

Then, in a step s501, it is analyzed whether or not the number, which is obtained by adding the via patterns and the dummy pattern modules outputted through each of the steps s101-s104 and the step s103 within the via pattern peripheral area that is outputted in the step s102, is equal to or more than the second prescribed value, or it is equal to or less than a fourth prescribed value. Then, the judgment result thereof is outputted. Specifically, a negative judgment is outputted when the number obtained by adding the number of dummy via patterns contained in the dummy pattern modules 19a-19k and the number of via patterns is smaller than the second prescribed value, and when it is larger than the fourth prescribed value. Inversely, a positive judgment is outputted when the number obtained by adding the number of dummy via patterns contained in the dummy pattern modules 19a-19k and the number of via patterns is equal to or more than the second prescribed value, and when it is equal to or less than the fourth prescribed value. The fourth prescribed value is a value defined by the manufacturing device and the manufacturing method of a semiconductor integrated circuit, which is defined to prevent manufacture problems that occur when the total number of the dummy via patterns contained in the dummy pattern modules and the via patterns is too large. Examples of the manufacture problems are short-circuits and the like generated between wirings on the second wiring layer, which may occur when residual substance of metal is formed on the interlayer insulating film due to under-etching.

Then, excessive dummy pattern modules are eliminated in a step s502. That is, when the result of judgment performed in the step s501 is negative, indicating that the sum of the number of via patterns and the number of dummy pattern modules exceeds the fourth prescribed value, a part of the dummy pattern modules is eliminated to output the remaining dummy pattern modules.

In a specific example, only dummy pattern modules disposed on odd-number wiring grid lines are outputted in order to thin out the dummy pattern modules. In FIG. 11A, reference numeral 21a indicates an odd-number wiring grid line in the wiring grid 16a obtained in the step s104, and 21b indicates an odd-number wiring grid line in the wiring grid 16b. hi this step, the dummy pattern modules are disposed only at the intersections of the odd-number wiring grid line 21a and the odd-number wiring grid line 21b among the intersections of the wiring grid 16a and the wiring grid 16b. As a result, the dummy pattern modules 19b and 19g are outputted. FIG. 11B shows the result obtained by thinning out the dummy pattern modules in this manner.

As described above, with the method according to the third embodiment of the present invention, the number of the dummy pattern modules outputted in the dummy pattern module selecting step s301 can be decreased through the via number judging step s501 and the dummy pattern module eliminating step s502. This prevents manufacture problems caused by an excessively large number of dummy pattern modules. The manufacture problems to be avoided includes short-circuits and the like generated between wirings on the second wiring layer, which may occur when, for example, residual substance of metal is formed on the interlayer insulating film due to under-etching.

Even though only the dummy pattern modules on the odd-number wiring grid lines are outputted in the dummy pattern module eliminating step s502 in the above-described case, it is not limited to that case. Modifications are possible such that only the dummy patterns on the even-number wiring grid lines are outputted, or only the dummy pattern modules positioned near the via pattern 4 are outputted while eliminating the dummy pattern modules positioned far from the via pattern 4. In that case, the dummy pattern modules are eliminated in decreasing order of distance from the via pattern 4 while setting the sum of the via pattern 4 and the dummy via patterns to be equal to or more than the second prescribed value and equal to or less than the fourth prescribed value. When dummy via pattern modules positioned distant from the via pattern 4 are eliminated, manufacture inconveniences caused by an excessively large number of via patterns and dummy via patterns can be more securely suppressed at least in the periphery of the via patterns.

FIG. 10 illustrates the case where the steps s501 and s502 are performed after the step s301. However, the steps s501 and s502 may be performed after the step s104 without performing the step s301.

### Fourth Embodiment

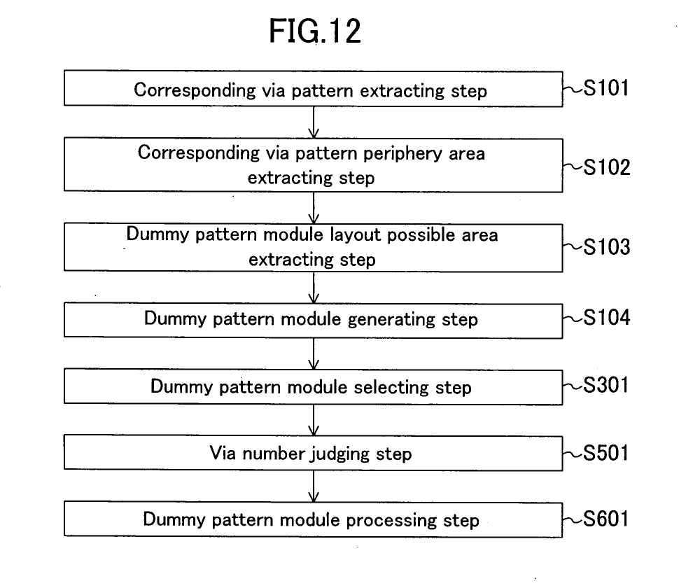

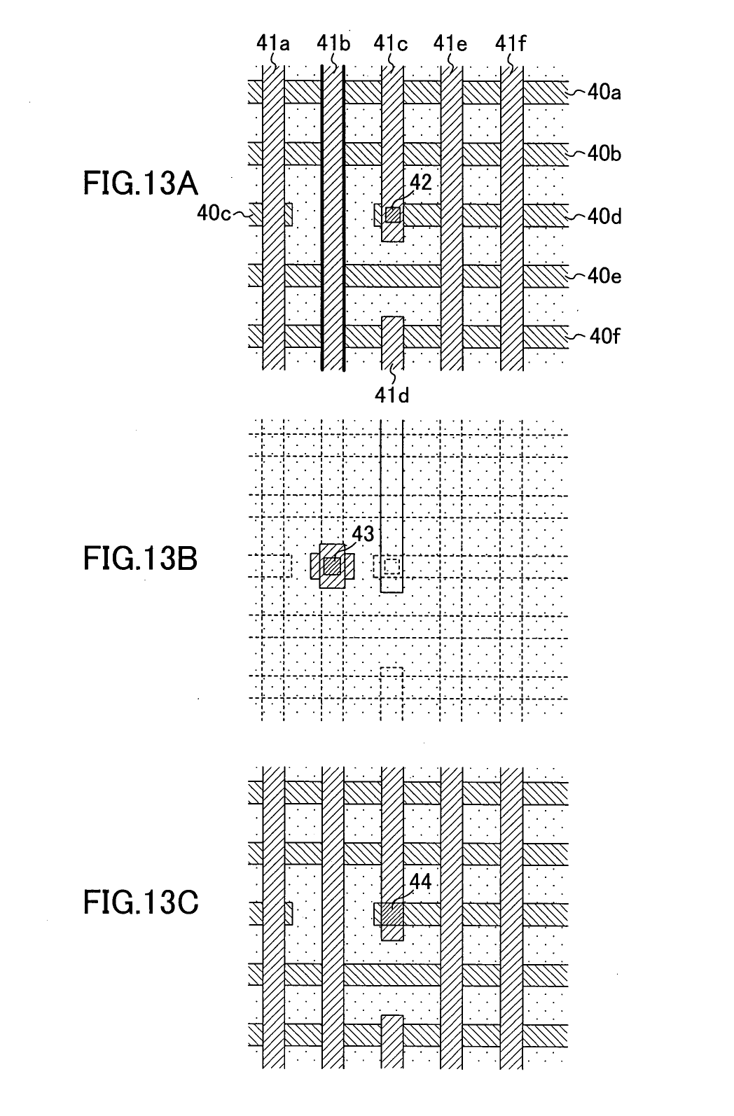

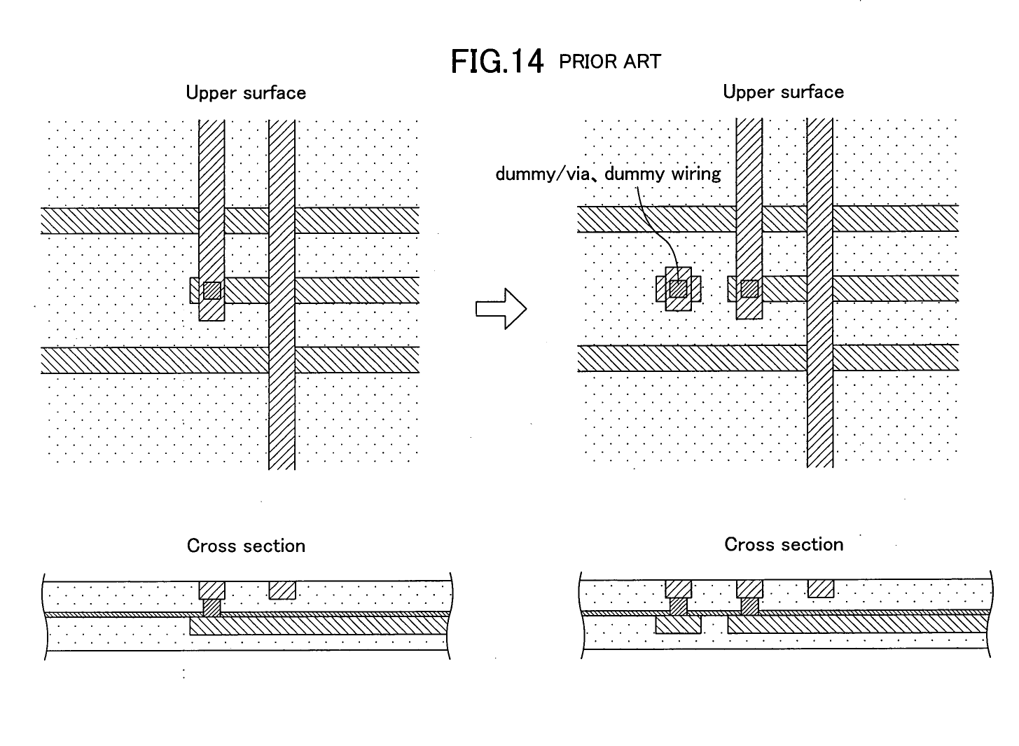

FIGS. 12 is a flowchart for illustrating the wiring auxiliary pattern generating method according to a fourth embodiment of the present invention. FIGS. 13A, 13B, and 13C are. plan views for describing the wiring auxiliary pattern generating method according to the fourth embodiment, which respectively illustrate actual pattern examples.

FIG. 13A shows the layout of the semiconductor substrate when viewed from above, and FIG. 13B shows a semiconductor integrated circuit resulting from generating the wiring auxiliary pattern on the wiring pattern example of FIG. 13A by the method of this embodiment. Further, FIG. 13C illustrates a via pattern 44 after being corrected. In FIG. 13A, reference numerals 40a-40f are the first wiring patterns disposed on the first wiring layer, and 41a-41f are the second wiring patterns disposed on the second wiring layer. A via pattern 42 electrically connects the first wiring pattern 40a and the second wiring pattern 41c. Further, the second wiring pattern 41b is the wiring pattern that corresponds to each critical path.

The wiring auxiliary pattern of this embodiment is generated in the following manner.

First, the steps s101-s104, the step s301, and the step s501 shown in FIG. 12 are carried out.

In the steps s101-s104, a dummy pattern module 43 shown in FIG. 13B is outputted in the same manner as the method of the first embodiment. In the subsequent step s301, the dummy pattern module 43 disposed on the second wiring pattern 41b that corresponds to the critical path is eliminated in the same maimer as the method of the second embodiment. Then, in the step s501, there is performed an analysis to check whether or not the sum of dummy via patterns contained in the dummy pattern modules outputted through the steps s101-s104, the step s301 and the via patterns exceeds the second prescribed value, and whether or not the sum is less than the fourth prescribed value in the same maimer as the method of the third embodiment, and the result thereof is outputted. Specifically, it is judged (positive or negative) by counting the number of via patterns 42, since the dummy pattern module 43 is eliminated in the step s301.

Then, when a negative judgment is outputted in the via number judging step s501, indicating that the sum of the via patterns and the dummy via patterns contained in the dummy pattern modules is less than the second prescribed value, enlarging processing is performed on the via pattern 42 for correcting the pattern shape, and the processing result is outputted as a corrected via pattern 44 in a dummy pattern module processing step s601.

As described above, when the sum of the via patterns and the dummy via patterns contained in the dummy pattern modules outputted in the dummy pattern module selecting step s301 is less than the second prescribed value, it is possible with the method of the embodiment to suppress generation of manufacture problems that are caused when the number of the dummy pattern modules is excessively small, through correcting the shape of the via pattern with enlarging processing by executing the via number judging step s501 and the dummy pattern module processing step s601. Examples of the manufacture problems may be that: depending on the wiring forming step, after forming the via holes, residual substances remain within the via holes when eliminating the wiring pattern part in the part where the thickness of ARC applied before forming the upper-layer wiring pattern is thicker than that of the area with densely disposed vias; and metal cannot be sufficiently filled in via holes that connect the lower-layer wiring (the first wiring) and the upper-layer wiring (the second wiring), so that disconnection is generated at this part.

Although the case of performing enlarging processing on the via patterns in the dummy pattern module processing step s601 is described herein, it is not limited to that case. The shape of the via patterns can be modified in various ways insofar as generation of the residual substance within the via holes is suppressed.

As described above, in the case where the result of judgment performed in the via number judging step s501 is negative, the step s601 may be performed if the sum of the via patterns and the dummy via patterns is less than the second prescribed value, and the step s502 may be performed if the sum exceeds the fourth prescribed value. Further, when the result judgment performed in the step s501 is positive, the dummy pattern modules obtained in the step s301 are used, as they are, for designing a semiconductor integrated circuit.

The semiconductor device and the wiring auxiliary pattern generating method according to the present invention described above can reduce variations in the interlayer film thickness generated during the manufacture process of the semiconductor device, so that the device and the method are particularly effective for reducing failures caused due to disconnection of vias.

What is claimed is:

1. A semiconductor device comprising:
first wirings formed on a semiconductor substrate;
an interlayer insulating film formed on the first wirings;
second wirings formed on the interlayer insulating film;
vias for connecting the first wirings and the second wirings through the interlayer insulating film;
first dummy wirings formed on a same wiring layer as that of the first wirings;
second dummy wirings formed on a same wiring layer as that of the second wirings;
first dummy vias for connecting the first dummy wirings and the second wirings; and
second dummy vias for connecting the second dummy wirings and the first wirings.

2. The semiconductor device according to claim 1, wherein:
the first dummy wirings are not electrically connected to the first wirings; and
the second dummy wirings are not electrically connected to the second wirings.

3. The semiconductor device according to claim 1, wherein:
among the first wirings, a first wiring that constitutes a clock line or a critical path is connected neither to the second dummy vias nor to the second dummy wirings; and
among the second wirings, a second wiring that constitutes a clock line or a critical path is connected neither to the first dummy vias nor to the first dummy wirings.

4. A wiring auxiliary pattern generating method for a semiconductor device, the semiconductor device including first wirings, second wirings positioned above the first wirings, and vias for connecting the first wiring and the second wiring, the method comprising the steps of:
(a) extracting, when the semiconductor device is sectioned into each area having a first prescribed value in size both longitudinally and laterally, via patterns that are disposed in an area where number of the via patterns is smaller than a second prescribed value, the via patterns being extracted from layout CAD data of the semiconductor device including information on a first wiring pattern as a wiring pattern of the first wirings, a second wiring pattern as a wiring pattern of the second wirings, and a via pattern as a pattern of the vias;
(b) performing graphic enlarging processing by using a third prescribed value with one of the corresponding via patterns extracted in the step (a) as a center of enlargement, and outputting a peripheral area of the corresponding via pattern;
(c) extracting, from the peripheral area of the corresponding via pattern, an area capable of generating a dummy pattern module that is constituted with a first dummy wiring pattern disposed on a same wiring layer as that of the first wiring pattern, a second dummy wiring pattern disposed on a same wiring layer as that of the second wiring pattern, and a dummy via pattern for connecting the first dummy wiring pattern and the second dummy wiring pattern; and
(d) disposing, in the area extracted in the step (c), dummy pattern modules that are only connected either to the first wiring pattern or to the second wiring pattern.

5. A wiring auxiliary pattern generating method for a semiconductor device, the semiconductor device including first wirings, second wirings positioned above the first wirings, and vias for connecting the first wiring and the second wiring, the method comprising the steps of:
(a) generating areas having a first prescribed value both longitudinally and laterally with respective vias serving as a center of each area, the areas being generated on the basis of layout CAD data of the semiconductor device including information on a first wiring pattern as a wiring pattern of the first wirings, a second wiring pattern as a wiring pattern of the second wirings, and a via pattern as a pattern of the vias, and extracting a via pattern that is disposed at the center of an area where number of the via patterns in that area is smaller than a second prescribed value;
(b) performing graphic enlarging processing by using a third prescribed value with the corresponding via pattern extracted in the step (a) as a center of enlargement, and outputting a peripheral area of the corresponding via pattern;
(c) extracting, from the peripheral area of the corresponding via pattern, an area capable of generating a dummy pattern module that is constituted with a first dummy wiring pattern disposed on a same wiring layer as that of the first wiring pattern, a second dummy wiring pattern disposed on a same wiring layer as that of the second wiring pattern, and a dummy via pattern for connecting the first dummy wiring pattern and the second dummy wiring pattern; and
(d) disposing, in the area extracted in the step (c), the dummy pattern modules that are only connected either to the first wiring pattern or to the second wiring pattern.

6. The wiring auxiliary pattern generating method according to claim 4, wherein the step (c) includes:
(cl) applying graphic enlarging processing on the first wiring pattern in the peripheral area of the corresponding via pattern by using a value that is equal to or more than a minimum space between the first wiring patterns defined in a design rule, and outputting a result of the graphic enlarging processing as a first layout prohibited area where layout of the first dummy wiring pattern is prohibited;
(c2) applying graphic enlarging processing on the second wiring pattern in the peripheral area of the corresponding via pattern by using a value that is equal to or more than a minimum space between the second wiring patterns defined in a design rule, and outputting a result of the graphic enlarging processing as a second layout prohibited area where layout of the second dummy wiring pattern is prohibited; and
(c3) performing graphic inverting processing respectively on the first layout prohibited area and the second layout prohibited area, performing graphic exclusive OR operation processing on each of outputted areas, and outputting results of the processing as areas capable of generating the dummy pattern module.

7. The wiring auxiliary pattern generating method according to claim 4, further comprising (e) selecting, among the dummy pattern modules outputted in the step (d), selects and outputs only a dummy pattern module that is disposed in an area other than an area where there are formed an analog circuit and a memory circuit whose circuit operations may be influenced by addition of the first dummy wiring or the second dummy wiring and the dummy via pattern, and outputting the dummy pattern module.

8. The wiring auxiliary pattern generating method according to claim 4, further comprising the steps of:
(f) extracting a net list containing signal path information regarding signals that may have delay fluctuations from net list CAD data of the semiconductor device;
(g) extracting a wiring pattern contained in the net list that is extracted in the step (f); and
(h) eliminating a dummy pattern module positioned on the wiring pattern extracted in the step (g), among the dummy pattern modules outputted in the step (d).

9. The wiring auxiliary pattern generating method according to claim 7, wherein the net list extracted in the step (f) includes a critical path.

10. The wiring auxiliary pattern generating method according to claim 8, wherein the net list extracted in the step (f) includes a clock line.

11. The wiring auxiliary pattern generating method according to claim 4, further comprising the steps of:
at least after the step (d), (i) judging whether or not a sum of the corresponding via patterns and the dummy via patterns disposed in the area extracted in the step (b) is equal to or more than the second prescribed value, and whether or not the sum is equal to or less than a fourth prescribed value; and
(j) processing the dummy via patterns when it is judged in the step (i) that the sum of the corresponding via patterns and the dummy via patterns is smaller than the second prescribed value, and reducing the dummy pattern modules when the sum is larger than the fourth prescribed value.

12. The wiring auxiliary pattern generating method according to claim 11, wherein, when it is judged in the step (i) that the sum of the corresponding via patterns and the dummy via patterns is smaller than the second prescribed value, graphic enlarging processing is performed on the dummy via patterns and the corresponding via patterns in the step (j) by using a fifth prescribed value.

13. The wiring auxiliary pattern generating method according to claim 11, wherein, when it is judged in the step (i) that the sum of the corresponding via patterns and the dummy via patterns is larger than the fourth prescribed value, dummy pattern modules distant from the via patterns are eliminated in the step (j), among the dummy pattern modules disposed within the area that is extracted in the step (b).

14. The wiring auxiliary pattern generating method according to claim 11, wherein, when it is judged in the step (i) that the sum of the corresponding via patterns and the dummy via patterns is larger than the fourth prescribed value, the dummy pattern modules connected to the first wiring patterns disposed on every other wiring grid lines and the dummy pattern modules connected to the second wiring patterns disposed on every other wiring grid lines are eliminated in the step (j).
